(19) United States
(12) Patent Application Publication
(10) Pub. No.: US 2011/0039079 A1
(43) Pub. Date: Feb. 17, 2011

(54) STRUCTURED SUBSTRATE GLASS FOR LED'S AND METHOD FOR PRODUCTION THEREOF

(75) Inventors: Matthias Bockmeyer, Mainz (DE); Eveline Rudigier-Voigt, Mainz (DE); Andreas Gier, Saarbruecken (DE)

Correspondence Address: OHLANDT, GREELEY, RUGGIERO & PERLE, LLP, ONE LANDMARK SQUARE, 10TH FLOOR, STAMFORD, CT, 06901, US

(73) Assignee: Schott AG

(21) Appl. No.: 12/850,264

(22) Filed: Aug. 4, 2010

(30) Foreign Application Priority Data
Aug. 5, 2009 (DE) 10 2009 036 135.9

(51) Int. Cl. B32B 3/10; C08L 83/04; B32B 5/00; B05D 3/00; B05D 3/12; C08F 2/48

(52) U.S. Cl. 428/195.1; 524/588; 428/339; 427/331; 427/358; 427/508

(57) ABSTRACT

A composite material designed as a substrate glass for LED's is provided. The composite material includes a structured coating made of a hybrid polymer matrix that contains nanoparticles made of an oxide.

### CROSS REFERENCE TO RELATED APPLICATIONS

This application claims benefit under 35 U.S.C. §119(a) of German Patent Application No. 10 2009 036 135.9, filed Aug. 5, 2009, the entire contents of which are incorporated herein by reference.

### BACKGROUND OF THE INVENTION

1. Field of the Invention

The invention relates to a composite material that is designed in particular as substrate glass for light emitting diodes (“LED's”), and a method for the production thereof.

2. Description of Related Art

Organic LED's (usually called OLED's) have been continuously improved in recent years, which addresses efficiency and service life. Nevertheless, there is a great need for improving such LED's, especially to be able to make competitive products available for conventional LED technology.

Usually, only about 20 to 25% of the light produced in the emitter layer is emitted by LED's. A large fraction of the light generated remains in guided optical modes within the organic layers or the substrate. A portion of this lost light can be attributed to total reflections at the substrate/air interface.

Possibilities are known from the prior art for reducing these losses of light.

For example, diffuser screens, microlenses, or structured surfaces can be applied to the air/substrate interface and the losses of light due to total reflections can be reduced in this way. A light-scattering coating is described, for example, in WO 2005/018010. The light output can also be improved by structuring on the side of the substrate facing the emitter layer, since the light captured in modes by a non-planar substrate can be at least partially decoupled. A grooved surface structure is described, for example, in GB 2361356 A.

Besides these, there are other sometimes truly costly methods, all of which are based on diffractive or refractive structures. Thus, for example, light-scattering gratings, two-dimensional photonic structures, or holograms are known.

The application of structuring to the top and/or bottom face of the substrate is a common feature of all these approaches.

Polymers that are hardened by electromagnetic radiation are also known, for example, for the application of microstructured transparent coatings.

The lower index of refraction of polymers compared to the substrate is detrimental as a rule, and this in turn can lead to total reflections. Sufficiently economical and durable polymer layers with an index of refraction greater than 1.6 have not yet been developed. It is particularly questionable whether adequate thermal and mechanical resistance and adequate long-term durability can be achieved with polymers.

### BRIEF SUMMARY OF THE INVENTION

The task underlying the invention is therefore to make available a coating and a method for making a coating, by means of which structured surfaces can be produced in a simple manner. Losses of light due to total reflections are to be reduced by the structured surface. The coating will also have adequate long-term stability.

The invention relates to a composite material that is provided, in particular, as substrate glass for LED's.

The composite material comprises a transparent substrate, preferably with an index of refraction greater than 1.6, with special preference greater than or equal to 1.7, and having a structured coating made of a matrix in which nanoparticles are embedded, and which has an index of refraction of greater than 1.6, preferably greater than or equal to 1.7.

According to the invention in a generalized version, the transparent substrate comprises a structured coating on at least one side made of a material that includes nanoparticles, preferably consisting of an oxide, and which has an index of refraction greater than 1.6.

In particular, a hybrid polymer matrix is used as the matrix. The hybrid polymer matrix preferably has an inorganic degree of condensation greater than or equal to 50%, preferably greater than 70%. The inventors have discovered that a hybrid polymer layer to which nanoparticles, preferably as oxide particles, are added to increase the index of refraction, is suitable in a special manner for producing diffractive or refractive microstructures on a substrate glass in an especially simple manner. An organic/inorganic hybrid polymer layer is applied as the hybrid polymer matrix, in particular, by a sol-gel method. This hybrid polymer serves as the matrix for preferably oxide nanoparticles. The matrix can have high temperature resistance and long-term durability because of the inorganic components. At the same time, crosslinking reactions and with them a strengthening can be brought about by electromagnetic radiation via organic groups, for example. A hybrid polymer matrix in the context of the invention also means a coating in which organic constituents have been at least partially removed and/or decomposed by thermal hardening. The nanoparticles preferably have an index of refraction greater than or equal to 1.9, preferably greater than or equal to 2.1. High-refraction oxides are particularly suitable as nanoparticles. Examples are TiO₂ (anatase or rutile), ZrO₂, Y₂O₃-stabilized ZrO₂, CaO-stabilized ZrO₂, MgO-stabilized ZrO₂, CeO₂-stabilized ZrO₂, MgO, CaO, pyrochlores of Zr/Ti/Hf/Nb such as SmTi₂O₇, LaZr₂O₇, CeTi₂O₇, CeO₂, La₂O₃, LaHf₂O₇, Gd-doped CeO₂, HfO₂, Al-doped ZnO, In-doped ZnO, Sb-doped ZnO, SnO₂ and/or ZnO. A structured coating with an index of refraction greater than 1.7, preferably greater than 1.75, can be made available with the invention. The index of refraction can be relatively well adapted to the index of refraction of the substrate glass and to the index of refraction of the layers of an LED.

The structuring is preferably a nano- or microstructuring. The structuring in particular is applied in a layer with a thickness between 10 nm and 200 μm, especially 500 nm and 30 μm. Both diffractive and refractive structures can be made available with the invention. The invention is therefore suitable for a plurality of known structurings.

A coating that is diffusely scattering at least in sections is provided, in particular.

However, holograms, Fresnel lenses, lens arrays, binary gratings, or double-refracting structures can be made with a structured coating according to the invention.

The structured coating can have a periodic structuring, for example. However, irregular structures are also conceivable. The structured coating according to the invention can be formed either on the side of the substrate facing the LED or on the side facing away from it. A substrate that has a structured coating on both sides is also conceivable. Nanoparticles, in particular, formed as oxide particles, which have an index of refraction 0.1 to 1.8 higher than the refraction index of the matrix, with special preference 0.5 to 1.5 higher, are preferably used.

The transparent substrate is preferably a glass substrate and especially a substrate with a refractive index greater than 1.6; a high-refracting substrate glass is therefore preferably used. Examples of high-refracting glasses composed of or comprising the following oxides in different compositions are: SiO₂, B₂O₃, Bi₂O₃, P₂O₅, K₂O, Cs₂O, SrO, GeO₂, Al₂O₃, Li₂O, Na₂O, CaO, BaO, ZnO, La₂O₃, Gd₂O₃, Y₂O₃, Ta₂O₅, Nb₂O₅, TiO₂, ZrO₂, WO₃, As₂O₃, Sb₂O₃, TiO₂, and/or ZrO₂. Structured coatings with refractive indices between 1.5 and 2.5, with special preference to a refractive index between 1.65 and 2.1, can be made available with the invention.

In an enhancement of the invention, in particular, to improve the mechanical properties or as converter material, non-oxide particles such as fluorides, sulfides, or selenides can be added. A structure with a broad aspect ratio between 0.1 and 10, preferably between 0.5 and 2, can be provided. The invention therefore makes it possible to produce structures with extremely varied optical activities.

The invention is thus suitable both for imagining optics, active matrix elements, etc, and also as diffuse scattering disks.

In particular, the structured coating can be made more thermally stable than known polymers. The coating is thus as a rule thermally resistant up to 200° C., preferably even up to at least 300° C.

The mechanical stability of the organic/inorganic composite material produced is usually better than in the case of purely organic layers.

For structured layers that are not to be formed as diffuse scattering layers, nanoparticles are particularly used that have been produced by solution precipitation or by hydrothermal treatment. Such particles usually have more regular structures.

In a special embodiment according to the invention, the preferably crystalline nanoparticles can be obtained as redispersible powders after removal of the solvent. It is especially preferred to use nanoparticles dispersed in nonaqueous, preferably alcoholic or nonpolar solvents. The nanoparticles for this purpose are preferably stabilized by means of surface-active reagents. For example, these can be tetramethylammonium hydroxide, polyethylene, poly(lactic acid), poly(amino acid), polycaprolactone, poly(alkyl cyanoacrylate), para-toluenesulfonic acid, polyethylene oxide-block-poly(glutamic acid), and/or poly(sodium 4-styrenesulfonate). In a particularly preferred embodiment according to the invention, aqueous solutions of finely dispersed nanoparticles, such as those that can be prepared by methods familiar to one skilled in the art, for example, hydrothermal treatment or precursor powders, or can be commercially purchased, for example, from Sachtleben under the trade name XXS 100, are used to prepare alcoholic nanoparticle dispersions, for example, of crystalline ZrO₂ or TiO₂. These highly concentrated dispersions are covered with a solvent immiscible with water and a surface-active reagent is then added. By doing this, the nanoparticles execute a phase interchange and then become finely dispersed in the nonaqueous solvent.

Photoluminescent nanoparticles can be added in an enhancement of the invention. These particles can either be contained in the layer in addition to the oxide particles, but it is also conceivable to provide oxide particles with photoluminescent properties. Nanoparticles with photoluminescent properties can be composed of or comprise the following materials doped with main group elements and/or subgroup elements and/or rare earths: Y₂O₃, LaPO₄, YVO₃, ZnSiO₃, ZnGeO₃, ZrGeO₃, YAlO₃, Y₃Al₅O₁₂, SrAl₂O₄, Sr₄Al₁₄O₂₅, (Ca, Sr, Ba)S, (Ca, Sr, Ba)(Ga, Al, Y)₂S₄, (Ca, Sr, Ba)Si₂N₂O₂, SrSiAl₂O₃N₂, (Ca, Sr, Ba)₂Si₅N₈ and/or CaAlSiN₃.

Dopants can be Dy, Mn, Eu, Er, Nd, Mn, Zn, Sb, Ce, Y, Gd, Tb and/or Lu, for example, especially in various oxidation states.

The invention also relates to a method for preparing a composite material, especially a composite material described above.

According to the invention, a transparent substrate is provided, onto which nanoparticles are applied, in particular provided as a sol-gel material comprising oxide particles. The nanoparticles, particularly as oxide particles, are preferably added to the sol-gel material as a dispersion. The nanoparticles, especially as oxide particles, are preferably crystalline.

A sol-gel material is preferably used with a precursor from which a hybrid polymer matrix, particularly an organic/inorganic hybrid polymer matrix, is formed. The hybrid polymer matrix is preferably made amorphous.

The hybrid polymer matrix, in particular, is filled with a material composed of or comprising a condensate of one or more hydrolyzable and condensable or condensed silanes and/or metal alkoxides, particularly of Ti, Zr, Al, Nb, Hf, and/or Ge, and/or their thermal rearrangement or decomposition products.

For example, these condensable constituents can be from the group composed of acrylosilanes, epoxysilanes, acryloalkoxysilanes, acryloepoxysilanes, epoxyalkoxysilanes, allylsilanes, vinylsilanes, fluoroalkylsilanes, aminosilanes, alkoxysilanes, metal alcoholates, metal oxide acrylates, metal oxide methacrylates, and/or metal oxide acetylacetonates.

They are especially the following substances, for example: Methacryloxypropylsilane, glycidylpropylsilane, zirconium secondary butoxide acrylate, titanium ethoxide acrylate, titanium propoxide acrylate, zirconium secondary butoxide methacrylate, titanium ethoxide methacrylate, titanium propoxide methacrylate, tetraethoxysilane, tetramethoxysilane, methyltriethoxysilane, methyltrimethoxysilane, ethyltrimethoxysilane, propyltrimethoxysilane, mercaptopropyltrimethoxysilane, aminopropylsilane, vinyltriethoxysilane, allyltriethoxysilane, phenyltriethoxysilane, triethoxysilylpropylsuccinic anhydride, and/or fluorooctylsilane.

The condensate is characterized in that the inorganic degree of condensation of the hydrolyzate is equal to or greater than 50%, preferably greater than 70%.

The sol-gel material can be applied readily even on large surfaces, for example, by dipping, spraying, roller coating, flooding, ink jet, pad printing, flexographic printing, screen printing, etc.

Screen printing represents an especially preferred method of application.

The sol-gel layer that is formed is then structured and hardened. Large-area substrate glasses can be provided with a high-refracting structured coating in a simple manner with the invention.

For this purpose, oxide particles with an index of refraction greater than 1.9, with special preference greater than 2.1, are preferably added. In an embodiment of the invention, the liquid sol is structured by means of an embossing die and is hardened during the contact with the embossing die.

A photoinitiator is admixed with the sol-gel for this purpose, for example, and hardening is performed by means of electromagnetic radiation, particularly by means of UV light. Because of the hardening while the layer is in contact with the embossing die, the sol-gel layer already has sufficient stability to be subjected to further hardening steps as needed.

Thus, a thermal hardening, in particular, can also follow the hardening with light.

In a special embodiment, the hardening is performed by a simultaneous combination of UV hardening and thermal hardening.

An embossing die can be used as the stamping tool, for example. In an alternative embodiment of the invention, a roller can also be used as the stamping tool. Another example for producing a structured coating is pad printing, flexographic printing, and/or another transfer method.

The sol-gel can contain a methacrylate, an acrylate, or an epoxide, in particular, as the thermally and/or UV-crosslinking component.

Organic peroxides in the form of diacyl peroxides, peroxydicarbonates, alkyl peresters, dialkyl peroxides, perketals, ketone peroxides, and/or alkyl hydroperoxides are preferably used as thermal initiators. Dibenzoyl peroxide, tert-butyl perbenzoate, and/or azobisisobutyronitrile are examples of such thermal initiators. 1-Methylimidazole is an example of a cationic thermoinitiator.

Radical photoinitiators, for example 1-hydroxycyclohexyl phenyl ketone and/or benzophenone are preferably used as UV initiators for acrylate- or methacrylate-based layer systems. Cationic photoinitiators, for example from the group of iodonium salts and/or sulfonium salts, and nonionic photoinitiators, for example such as diphenyliodonium nitrate, diphenyliodonium triflate, diphenyliodonium p-toluenesulfonate, N-hydroxynaphthalimide triflate, N-hydroxyphthalimide triflate, thiobis(triphenylsulfonium hexafluorophosphate), and/or (4-methylphenyl)[4-(2-methylpropyl)phenyl](−1)hexafluorophosphate, are preferably used for glycidyl-based sol-gel layers.

The groups crosslinking by inorganic hydrolysis or condensation in the sol-gel process can be the following functional groups, for example:

TiR₃, ZrR₃, SiR₄, AlR₃, TiR₃(OR), TiR₂(OR)₂, ZrR₂(OR)₂, ZrR₃(OR), SiR₃(OR), SiR₂(OR)₂, TiR(OR)₃, ZrR(OR)₃, AlR₂(OR), AlR₁(OR)₂Ti(OR)₄, Zr(OR)₄, Al(OR)₃, Si(OR)₄, SiR(OR)₃, and/or Si₂(OR)₆, and/or one of the following substances or groups of substances with OR: alkoxy such as preferably methoxy, ethoxy, n-propoxy, i-propoxy, butoxy, isopropoxyethoxy, methoxypropoxy, phenoxy, acetoxy, propionyloxy, ethanolamine, diethanolamine, triethanolamine, methacryloxypropyl, acrylate, methyacrylate, acetylacetone, ethyl acetoacetate, ethoxyacetate, methoxyacetate, methoxyethoxyacetate and/or methoxyethoxyethoxyacetate, and/or one of the following substances or groups of substances with R: Cl, Br, F, methyl, ethyl, n-propyl, butyl, ally, vinyl, glycidylpropyl, methacryloxypropyl, aminopropyl, and/or fluorooctyl.

The oxide particles are preferably nanoparticles with an average diameter between 0.5 and 200 nm, with special preference between 4 and 25 nm.

In a preferred embodiment according to the invention, these nanoparticles are embedded reactively in the network of the layer. This means that a chemical reaction of the preferred oxide surface and its hydroxyl groups with the organic or inorganic crosslinkable functionalities of the matrix has taken place.

The nanoparticles are preferably chemically combined with silanol groups or other hydroxyl groups of metal oxides and/or their organometallic or hybrid polymer compounds.

In this preferred embodiment, therefore, no pores are formed between the nanoparticles and the surrounding layer, which otherwise would lead to a lowering of the index of refraction of the layer material.

A preferred hybrid polymeric matrix according to the invention with an index of refraction greater than or equal to 1.65, preferably greater than or equal to 1.7, is composed of or contains more than or equal to 10 percent by volume, preferably more than or equal to 20 percent by volume, of especially high-refracting nanoparticles.

In a special embodiment according to the invention, constituents of the matrix can be polysiloxanes. For example, these can be methyl, phenylpolysiloxanes that are terminated, for example, by hydroxyl, glycidyl, and/or polyether.

It is a characteristic of a special embodiment that organic additives, for example, such as dipentaerythritol pentaacrylate, hexanediol diacrylate, trimethylolpropane triacrylate, and/or succinic anhydride are added to the coating as a hardener.

A thickener, for example, such as polydisperse silicic acid, cellulose, and/or xanthan, can be added to the sol-gel precursor for the preparation of layers according to the invention.

In a particular embodiment according to the invention, additives such as leveling aids, which can originate from the substance class of polyether-modified dimethylsiloxanes, for example, are added to the sol-gel coating solutions.

The thermal hardening of the layer is performed preferably at a temperature between 100 and 500° C.

The invention also relates to an LED. The layers necessary for preparing the LED are preferably applied to the composite material according to the invention.

Composite materials pursuant to the invention can be produced as follows, for example:

Preparation of the hydrolyzed lacquer formulation according to Example 1:

Methacryloxypropyltriethoxysilane (MPTES), tetraethoxysilane (TEOS), and methyltriethoxysilane (MTEOS) are placed in a container. In this example of embodiment, for example, about 0.6 mole of MPTES, about 0.2 mole of TEOS, and about 0.2 mole of MTEOS are used.

Then, 23 g of distilled water to which 3.44 g of para-toluenesulfonic acid has been added is added slowly to this solution with cooling and stirring. After stirring for 5 min, 700 g of a dispersion in n-butanol of 20 percent by weight anatase nanoparticles and a crystallite size of 10-15 nm is added.

After hydrolysis is complete, which can take about 24 hours, the hybrid polymer sol obtained with reactively embedded, finely dispersed, unagglomerated nanoparticles is diluted with methoxypropanol. A photoinitiator is added to the lacquer formulation. 1% (by weight if not otherwise stated) of the photoinitiator 1-hydroxycyclohexyl phenyl ketone, which is available under the trade name Irgacure 184®, based on the viscous hybrid polymer, can be added as the photoinitiator, for example.

After drying off the solvent, a polymeric or silicone-like embossing die with a raised impression is pressed into the low-viscosity, plastic gel film. The embossing die can be pressed down over an area (e.g. 10*10 cm²) at 0.1-2.0 bar. The embossing die consists of a material that is transparent in a wavelength range >230 nm. A periodic grating structure with a period of 350 nm and an aspect ratio of an average of 1 can be produced as the structure of the embossing die, for example. While the embossing die is in contact with the layer material, a first hardening of the layer is carried out by means of a UV lamp that emits in the wavelength region of about 250 nm.

After removing the embossing die, another UV-based layer hardening and a thermal layer hardening at 100-200° C. are carried out.

The average layer thickness of the stamped layer can be between 170 and 1000 nm. The aspect ratio of the stamped structure is 0.5-1.0. The layer material in this example of embodiment has a refractive index of about 1.7.

Preparation of the hydrolyzed lacquer formulation according to Example 2:

Methacryloxypropyltriethoxysilane (MPTES), tetraethoxysilane (TEOS), and methyltriethoxysilane (MTEOS) are placed in a container. In this example of embodiment, for example, about 0.75 mole of MPTES, about 0.2 mole of TEOS, and about 0.005 mole of MTEOS are used.

Then, 23 g of distilled water to which 3.44 g of para-toluenesulfonic acid has been added is added slowly to this solution with cooling and stirring. After stirring for 5 min, 700 g of a dispersion in n-butanol of 20 percent by weight anatase nanoparticles and a crystallite size of 10-15 nm is added.

This solution is combined with a solution of zirconium propoxide and methacrylic acid. For example, 0.75 mole MPTES, 0.02 mole TEOS, and 0.05 MTEOS, as well as a solution of 0.3 mole zirconium propoxide and 0.3 mole methacrylic acid can be used.

After hydrolysis is complete, which can take about 24 hours, the readily volatile solvent is removed in a rotary evaporator at 120 mbar and 40° C., and a photoinitiator is then added to the lacquer formulation. 2% (by weight, if not otherwise stated) of the photoinitiator 1-hydroxycyclohexyl phenyl ketone, which is available under the trade name Irgacure 184®, based on the viscous hybrid polymer, can be added as the photoinitiator, for example.

After drying off the solvent, a polymeric or silicone-like embossing die is pressed into the low-viscosity, plastic gel film. The embossing die is composed of a material that is transparent in a wavelength range >230 nm. A microoptical lens array consisting of hemispherical microlenses with a diameter of 7 μm and a structure depth of 3 μm can be provided as the structure of the embossing die. While the embossing die is in contact with the layer material, a first hardening of the layer is carried out by means of a UV lamp that emits in the wavelength region of about 250 nm.

After removing the embossing die, another UV-based layer hardening and a thermal layer hardening at 100-200° C. are carried out.

The average thickness of the embossed hybrid polymeric layer with elevated refractive index is between 3 and 5 μm. The layer material has a refractive index of about 1.7.

Preparation of the hydrolyzed lacquer formulation according to Example 3:

Gycidylpropyltriethoxysilane (GPTES), tetraethoxysilane (TEOS) and methyltriethoxysilane (MTEOS) are placed in a container. For example, about 0.6 mole GPTES, 0.2 mole TEOS, and 0.2 mole MTEOS are used. This solution is combined with a solution of aluminum secondary butoxide and ethyl acetate, for example 0.1 mole of each. To this solution is then added slowly with cooling and stirring an acidic dispersion of an aqueous nanoparticulate TiO₂ dispersion, with methanol and para-toluenesulfonic acid added to it. For example, about 28 g of a TiO₂ dispersion with 18 percent anatase by weight and a crystallite size of 7-12 nm, to which have been added about 60 g of methanol and 3.44 g of para-toluenesulfonic acid, can be added. After stirring for 5 min, 660 g of a dispersion in n-butanol of 20 percent by weight anatase nanoparticles and a crystallite size of 10-15 nm is added.

After hydrolysis is complete, which can take about 24 hours, the readily volatile solvent is removed in a rotary evaporator at 120 mbar and 40° C. bath temperature (for example, methanol/ethanol). A photoinitiator is added to the hybrid polymer sol obtained with reactively embedded, finely dispersed nanoparticles 0.2% (by weight, if not otherwise stated) of the cationic photoinitiator (4-methylphenyl)[4-(2-methylpropyl) phenyl](−1)hexafluorophosphate (Irgacure 250®), based on the viscous hybrid polymer, for example, can be added. A one-sided coating is then carried out by means of spin coating. After drying off the solvent, a polymeric or silicone-like embossing die is pressed into the low-viscosity, plastic gel film. The embossing die is composed of a material that is transparent in a wavelength range >230 nm. A grating structure composed of a crossed lattice with a period of 5 μm and a structure depth of 3 μm can be provided as the structure of the embossing die. While the embossing die is in contact with the layer material, a first hardening of the layer is carried out by means of a UV lamp that emits in the wavelength region of about 250 nm.

After removing the embossing die, another UV-based layer hardening and a thermal layer hardening at 200-300° C. are carried out.

The average glassy ceramic layer thickness of the stamped layer is between 4 and 5 μm. The layer material has a refractive index of about 1.7.

### BRIEF DESCRIPTION OF THE SEVERAL VIEWS OF THE DRAWINGS

FIGS. 1 to 4 show schematically a composite material in various steps of production; and

FIG. 5 shows a flow diagram for a schematic example of embodiment.

### DETAILED DESCRIPTION OF THE INVENTION

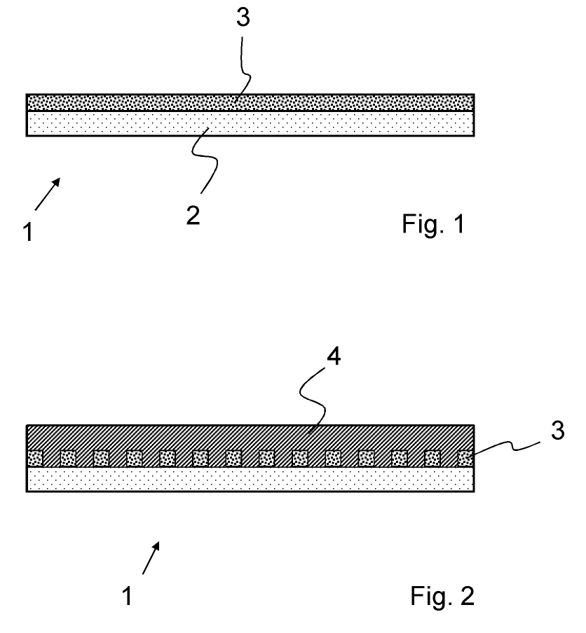

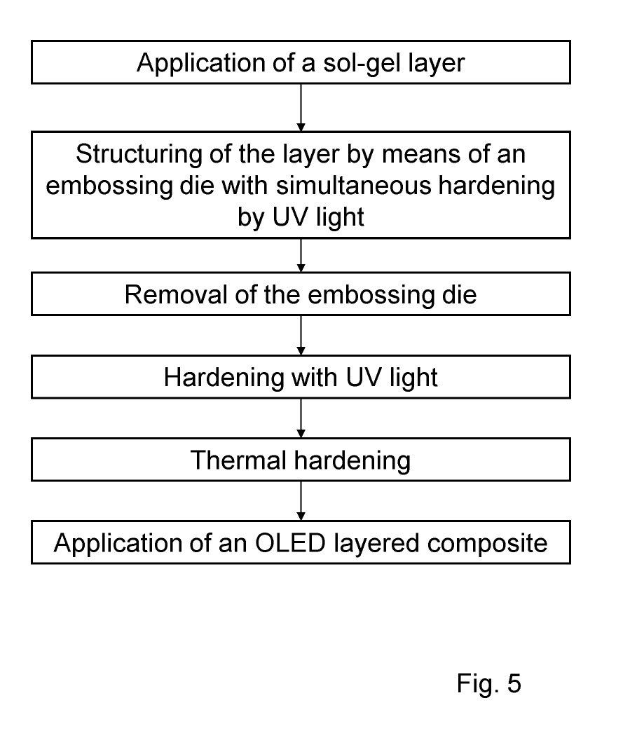

The invention will be explained in further detail below with reference to the drawings, FIG. 1 to FIG. 5. FIGS. 1 to FIG. 4, show schematically a composite material in various steps of production. FIG. 5 shows a flow diagram for a schematic example of embodiment.

As illustrated in FIG. 1, a transparent substrate 2 is first provided for the preparation of a composite material 1, onto which a sol-gel layer 3 comprising oxide particles is applied.

The sol-gel layer 3 can be applied, for example, by dipping, screen printing, spin coating, roller coating, or slit casting.

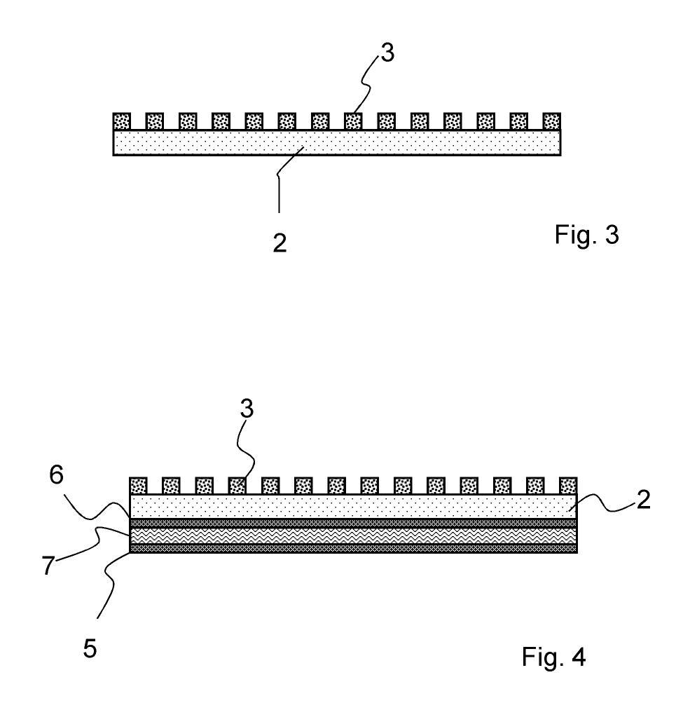

The sol-gel layer 3 is then structured as illustrated in FIG. 3 by means of an embossing die 4.

A photoinitiator is added to the sol-gel layer 3. While pressure is exerted on the sol-gel layer 3 by the embossing die, and it is thus in contact with the embossing die 4, a first hardening is carried out my means of UV light.

As illustrated in FIG. 3, the embossing die 4 is then lifted off and the previously low-viscosity sol-gel 3 has sufficient stability for the structuring to be retained.

Other hardening steps then preferably follow, and, in particular, the sol-gel layer is thermally hardened or baked in.

The composite material can then be used as the substrate for an LED, as is illustrated schematically in FIG. 4.

To this end, a cathode 6 is applied to the substrate, and between it and the anode 5 lying beneath it there is found an emitter layer 7.

It is to be understood that the LED here is illustrated here only greatly simplified, and in practice it generally has a plurality of other layers.

In this example of embodiment the sol-gel layer 3 that constitutes the structured coating is positioned as a cover layer at the glass/air interface.

In the context of the invention, a structured coating can also be positioned alternatively or additionally between the substrate 2 and the adjacent layers of the LED.

A method for producing a composite material will be explained schematically with reference to the flow diagram in FIG. 5.

A sol-gel layer is first applied that is then structured by means of an embossing die with simultaneous hardening with UV light.

The embossing die is then removed and another hardening is performed with UV light.

After hardening with UV light, the hybrid polymer is thermally hardened.

The composite material thus formed can then be used as the substrate for an LED and the other layers of an OLED layered composite are applied.

It is to be understood that the invention is not limited to a combination of the features described above, but that one skilled in the art will combine all features if it is technically feasible.

What is claimed is:

1. A composite material for light emitting diodes, comprising:
a transparent substrate with an index of refraction greater than 1.6;
a structured coating on the transparent substrate, the structured coating comprising a matrix in which nanoparticles are embedded, the matrix having an index of refraction of greater than 1.6.

2. The composite material according to claim 1, wherein the index of refraction of the transparent substrate and/or of the matrix is greater than or equal to 1.7.

3. The composite material according to claim 1, wherein the matrix is a hybrid polymer matrix.

4. The composite material according to claim 3, wherein the hybrid polymer matrix has an inorganic degree of condensation greater than or equal to 50%.

5. The composite material according to claim 4, wherein the inorganic degree of condensation is greater than 70%.

6. The composite material according to claim 1, wherein the matrix comprises a sol-gel matrix.

7. The composite material according to claim 1, wherein the nanoparticles have an index of refraction greater than or equal to 1.9.

8. The composite material according to claim 7, wherein the nanoparticles have an index of refraction greater than or equal to 2.1.

9. The composite material according to claim 1, wherein the structured coating has an index of refraction greater than 1.65.

10. The composite material according to claim 1, wherein the structured coating has an index of refraction greater than 1.7.

11. The composite material according to claim 1, wherein the nanoparticles comprise crystalline and/or partially crystalline nanoparticles.

12. The composite material according to claim 1, wherein the nanoparticles comprise oxide nanoparticles.

13. The composite material according to claim 1, wherein the structured coating comprises a fraction of nanoparticles by volume of greater than or equal to 10%.

14. The composite material according to claim 1, wherein the structured coating comprises a fraction of nanoparticles by volume of greater than 20%.

15. The composite material according to claim 1, wherein the index of refraction of the transparent substrate is greater than that of the structured coating.

16. The composite material according to claim 1, wherein the structured coating has a thickness between 10 nm and 200 μm.

17. The composite material according to claim 1, wherein the structured coating is, at least in sections, a diffusely scattering layer.

18. The composite material according to claim 1, wherein the structured coating comprises a structure selected from the group consisting of a hologram, a Fresnel lens, a lens array, a binary lattice, and a double-refracting structure.

19. The composite material according to claim 1, wherein the structured coating is of periodic design.

20. The composite material according to claim 1, wherein the nanoparticles have an index of refraction that is higher than an index of refraction of the matrix.

21. The composite material according to claim 1, wherein the structured coating has diffractive and refractive regions.

22. The composite material according to claim 1, wherein the structured coating has an index of refraction between 1.5 and 2.5.

23. The composite material according to claim 1, wherein the nanoparticles comprise non-oxide particles selected from the group consisting of fluoride particles, sulfide particles, selenide particles, and any combinations thereof.

24. The composite material according to claim 1, wherein the structured coating has a structure with an aspect ratio between 0.1 and 10.

25. A method for producing a composite material, comprising the steps of:
applying a liquid sol-gel material comprising nanoparticles to a transparent substrate;
structuring the liquid sol-gel material; and
hardening the liquid sol-gel material.

26. The method according to claim 25, wherein the step of structuring and hardening the liquid sol-gel material comprises contacting the liquid sol-gel material with an embossing die and hardening the liquid sol-gel material during contact with the embossing die.

27. The method according to claim 25, further comprising admixing a photoinitiator with the liquid sol-gel material, wherein the hardening comprises exposing the liquid sol-gel material to UV light.

28. The method according to claim 27, wherein hardening the liquid sol-gel material further comprises thermally hardening the liquid sol-gel material.

29. The method according claim 28, wherein the thermal hardening is carried out after exposing the liquid sol-gel material to UV light.

30. The method according to claim 28, wherein the thermally hardening step is performed at a temperature between 100 and 500° C.

31. The method according to claim 25, further comprising admixing a thermally or light crosslinking precursor to the liquid sol-gel material.

32. The method according to claim 31, wherein the crosslinking precursor is selected from the group consisting of a methacrylate, an acrylate, an epoxide, and any combinations thereof.
